(19) United States
(12) Patent Application Publication
(10) Pub. No.: US 2020/0395243 A1
(43) Pub. Date: Dec. 17, 2020

(54) MULTILAYER WIRING FORMING METHOD AND RECORDING MEDIUM

(71) Applicant: Tokyo Electron Limited, Tokyo (JP)

(72) Inventor: Mitsuaki Iwashita, Kikuchi-gun, Kumamoto (JP)

(21) Appl. No.: 16/971,450

(22) PCT Filed: Feb. 7, 2019
(86) PCT No.: PCT/JP2019/004424

§ 371 Date: Aug. 20, 2020

(30) Foreign Application Priority Data
Feb. 21, 2018 (JP) 2018-029174

(51) Int. Cl. H01L 21/768; C23C 18/16; C23C 18/38; H01L 21/31; H01L 21/288; H01L 23/532

(52) U.S. Cl. CPC H01L 21/76879; C23C 18/1619; C23C 18/1678; H01L 23/532; H01L 21/31; H01L 21/288; H01L 21/76874; C23C 18/38

(57) ABSTRACT

A multilayer wiring forming method includes filling a via, which is formed in an insulating film including an oxide film formed on a wiring of a substrate and is extended to the wiring, by forming an electroless plating film, which does not diffuse into the oxide film, from a bottom surface of the via while using the wiring, which is exposed at the bottom surface of the via, as a catalyst.

### TECHNICAL FIELD

The various aspects and embodiments described herein pertain generally to a multilayer wiring forming method and a recording medium therefor.

### BACKGROUND

Conventionally, as a way to form a multilayer wiring in a semiconductor wafer (hereinafter, simply referred to as “wafer”) as a substrate, there is known a method in which a barrier layer and a seed layer are stacked on an inner surface of a via which is formed in an insulating film provided on a wiring, and the inside of the via is then filled by performing an electrolytic plating processing (see, for example, Patent Document 1).

### PRIOR ART DOCUMENT

Patent Document 1: Japanese Patent Laid-open Publication No. 2013-194306

### DISCLOSURE OF THE INVENTION

### Problems to be Solved by the Invention

Exemplary embodiments provide a technique capable of forming a metal wiring within a via having a high aspect ratio.

### Means for Solving the Problems

In an exemplary embodiment, a multilayer wiring forming method includes filling a via, which is formed in an insulating film including an oxide film formed on a wiring of a substrate and is extended to the wiring, by forming an electroless plating film, which does not diffuse into the oxide film, from a bottom surface of the via while using the wiring, which is exposed at the bottom surface of the via, as a catalyst.

### Effect of the Invention

According to the exemplary embodiments, it is possible to form the metal wiring within the via having the high aspect ratio.

### BRIEF DESCRIPTION OF THE DRAWINGS

FIG. 1 is a schematic diagram illustrating a schematic configuration of a multilayer wiring forming system according to a first exemplary embodiment.

FIG. 2 is a cross sectional view illustrating a configuration of an electroless plating unit according to the first exemplary embodiment.

FIG. 3 is a schematic diagram illustrating a configuration of a CMP processing unit according to the first exemplary embodiment.

FIG. 4 is a cross sectional view illustrating a configuration of a heat treatment unit according to the first exemplary embodiment.

FIG. 5A is a first schematic diagram for describing a multilayer wiring forming processing according to the first exemplary embodiment.

FIG. 5B is a second schematic diagram for describing the multilayer wiring forming processing according to the first exemplary embodiment.

FIG. 5C is a third schematic diagram for describing the multilayer wiring forming processing according to the first exemplary embodiment.

FIG. 6A is a first schematic diagram for describing a multilayer wiring forming processing according to a second exemplary embodiment.

FIG. 6B is a second schematic diagram for describing the multilayer wiring forming processing according to a second exemplary embodiment.

FIG. 6C is a third schematic diagram for describing the multilayer wiring forming processing according to the second exemplary embodiment.

FIG. 7 is a flowchart illustrating a processing sequence in the multilayer wiring forming processing according to the first exemplary embodiment.

FIG. 8 is a flowchart illustrating a processing sequence in the multilayer wiring forming processing according to the second exemplary embodiment.

### DETAILED DESCRIPTION

Hereinafter, exemplary embodiments of a multilayer wiring forming method and a recording medium according to the present disclosure will be described in detail with reference to the accompanying drawings. The present disclosure is not limited to the exemplary embodiments to be described below. Further, it should be noted that the drawings are schematic and relations in sizes of individual components and ratios of the individual components may sometimes be different from actual values. Even between the drawings, there may exist parts having different dimensional relationships or different ratios.

<Outline of Multilayer Wiring Forming System>

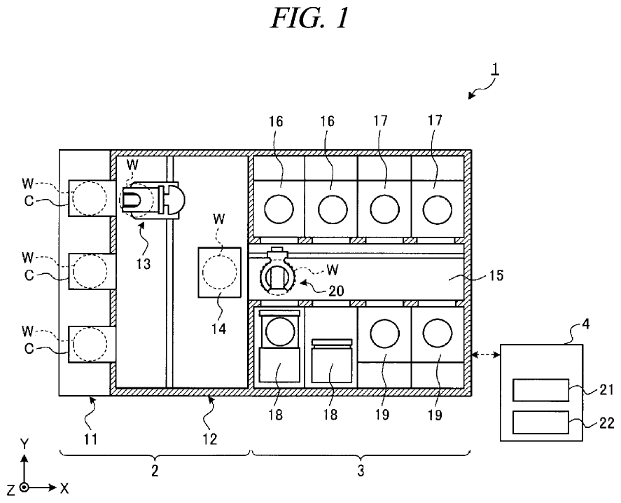

First, referring to FIG. 1, a schematic configuration of a multilayer wiring forming system 1 according to a first exemplary embodiment will be described in detail. FIG. 1 is a diagram illustrating the schematic configuration of the multilayer wiring forming system 1 according to the first exemplary embodiment. In the following, in order to clarify positional relationships, the X-axis, Y-axis and Z-axis which are orthogonal to each other will be defined. The positive Z-axis direction will be regarded as a vertically upward direction.

As depicted in FIG. 1, the multilayer wiring forming system 1 includes a carry-in/out station 2 and a processing station 3. The carry-in/out station 2 and the processing station 3 are provided adjacent to each other.

The carry-in/out station 2 is provided with a carrier placing section 11 and a transfer section 12. In the carrier placing section 11, carriers C each accommodating therein semiconductor wafers W (hereinafter, referred to as “wafers W”) horizontally are placed. Further, the wafer W is an example of a substrate.

The transfer section 12 is provided adjacent to the carrier placing section 11, and provided with a substrate transfer device 13 and a delivery unit 14. The substrate transfer device 13 is provided with a wafer holding mechanism configured to hold the wafer W. Further, the substrate transfer device 13 is movable horizontally and vertically and pivotable around a vertical axis, and transfers the wafer W between the carriers C and the delivery unit 14 by using the wafer holding mechanism.

The processing station 3 is provided adjacent to the transfer section 12. The processing station 3 is equipped with a transfer section 15, a plurality of electroless plating units 16, a plurality of CMP (Chemical Mechanical Polishing) processing unit 17, a plurality of heat treatment units 18, and a plurality of cleaning units 19.

The plurality of electroless plating units 16 and the plurality of CMP processing units 17 are arranged at one side of the transfer section 15, and the plurality of heat treatment units 18 and the plurality of cleaning units 19 are arranged at the other side of the transfer section 15. Further, the layout and the number of the electroless plating units 16, the CMP processing units 17, the heat treatment units 18 and the cleaning units 19 shown in FIG. 1 are just an example and are not limited to those shown in FIG. 1.

The transfer section 15 is provided with a substrate transfer device 20 therein. The substrate transfer device 20 is equipped with a wafer holding mechanism configured to hold the wafer W. Further, the substrate transfer device 20 is movable horizontally and vertically and pivotable around a vertical axis. The substrate transfer device 20 transfers the wafer W between the delivery unit 14, the electroless plating unit 16, the CMP processing unit 17, the heat treatment unit 18, and the cleaning unit 19 by using the wafer holding mechanism.

The electroless plating unit 16 is configured to perform a preset electroless plating processing on the wafer W transferred by the substrate transfer device 20. A configuration of the electroless plating unit 16 will be elaborated later.

The CMP processing unit 17 is configured to perform a preset CMP processing on the wafer W transferred by the substrate transfer device 20. A configuration of the CMP processing unit 17 will be described later.

The heat treatment unit 18 is configured to perform a preset heat treatment on the wafer W transferred by the substrate transfer device 20. A configuration of the heat treatment unit 18 will be explained later.

The cleaning unit 19 is configured to perform a preset cleaning processing on the wafer W transferred by the substrate transfer device 20. The cleaning unit 19 is, by way of example, a spin cleaning type cleaning device.

Further, the multilayer wiring forming system 1 includes a control device 4. The control device 4 is, for example, a computer, and includes a controller 21 and a storage 22.

The controller 21 includes various circuits and a microcomputer having a CPU (Central Processing Unit), a ROM (Read Only Memory), a RAM (Random Access Memory), an input/output port, and so forth.

The CPU of this microcomputer carries out controls over the transfer sections 12 and 15, the electroless plating units 16, the CMP processing units 17, the heat treatment units 18, the cleaning units 19, and so forth by reading out and executing programs stored in ROM.

Further, the programs may be recorded in a computer-readable recording medium and may be installed to the storage 22 of the control device 4 from this recording medium. The computer-readable recording medium may be, by way of non-limiting example, a hard disk (HD), a flexible disk (FD), a compact disk (CD), a magnet optical disk (MO), a memory card, or the like.

The storage 22 may be implemented by, for example, a semiconductor memory device such as a RAM or a flash memory, or a storage device such as a hard disk or an optical disk.

In the multilayer wiring forming system 1 configured as described above, the substrate transfer device 13 of the carry-in/out station 2 first takes out the wafer W from the carrier C placed in the carrier placing section 11, and then places the taken wafer W on the delivery unit 14. The wafer W placed on the delivery unit 14 is taken out from the delivery unit 14 by the substrate transfer device 20 of the processing station 3 and carried into the electroless plating unit 16.

The wafer W carried into the electroless plating unit 16 is subjected to the preset electroless plating processing by the electroless plating unit 16, and is then taken out of the electroless plating unit 16 and carried into the CMP processing unit 17 by the substrate transfer device 20.

The wafer W carried into the CMP processing unit 17 is subjected to the preset CMP processing by the CMP processing unit 17, and is then taken out of the CMP processing unit 17 and carried into the heat treatment unit 18 by the substrate transfer device 20.

The wafer W carried into the heat treatment unit 18 is subjected to the preset heat treatment by the heat treatment unit 18, and is then taken out of the heat treatment unit 18 and carried into the cleaning unit 19 by the substrate transfer device 20.

The wafer W carried into the cleaning unit 19 is subjected to the preset cleaning processing by the cleaning unit 19, and is then carried out of the cleaning unit 19 and placed in the delivery unit 14 by the substrate transfer device 20. Then, the wafer W placed in the delivery unit 14 after being completely processed is returned back into the carrier C of the placing section 11 by the substrate transfer device 13.

<Outline of Electroless Plating Unit>

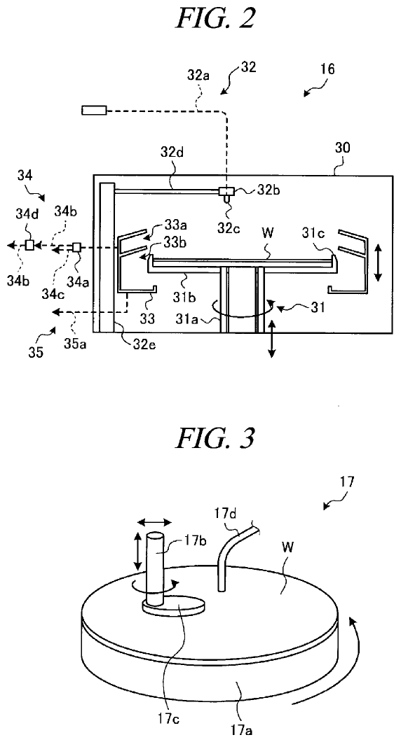

Now, referring to FIG. 2, a schematic configuration of the electroless plating unit 16 will be described. FIG. 2 is a cross sectional view illustrating the configuration of the electroless plating unit 16 according to the first exemplary embodiment. The electroless plating unit 16 is configured as, for example, a single-wafer type processing unit configured to process the wafers W one by one.

The electroless plating unit 16 is equipped with, as depicted in FIG. 2, a housing 30, a substrate holding/rotating device 31, a processing liquid supply mechanism 32, a cup 33, and liquid draining mechanisms 34 and 35.

The substrate holding/rotating device 31 is configured to hold and rotate the wafer W within the housing 30. The substrate holding/rotating device 31 includes a rotary shaft 31a, a turntable 31b, a wafer chuck 31c and a non-illustrated rotating mechanism.

The rotary shaft 31a is of a hollow cylindrical shape and is vertically extended within the housing 30. The turntable 31b is provided to an upper end of the rotary shaft 31a. The wafer chuck 31c is provided at an edge portion of a top surface of the turntable 31b to support the wafer W.

The substrate holding/rotating device 31 is controlled by the controller 21 of the control device 4, and the rotary shaft 31a is rotated by the rotating mechanism. Accordingly, the wafer W supported by the wafer chuck 31c can be rotated.

The processing liquid supply mechanism 32 is configured to supply a preset processing liquid onto a surface of the wafer W held by the substrate holding/rotating device 31. The processing liquid supply mechanism 32 includes a processing liquid supply 32a configured to supply the processing liquid onto the surface of the wafer W. The processing liquid is, for example, an electroless plating liquid.

Further, the processing liquid supply mechanism 32 includes a nozzle head 32b, and a nozzle 32c is fastened to the nozzle head 32b. This nozzle 32c is a nozzle corresponding to the processing liquid supply 32a.

The nozzle head 32b is fastened to a leading end of an arm 32d. This arm 32d is configured to be movable up and down, and is rotatably fixed to a supporting shaft 32e which is rotated by a non-illustrated rotating mechanism.

With this configuration, the processing liquid supply mechanism 32 is capable of discharging the preset processing liquid to a required position on the surface of the wafer W from a required height through the nozzle 32c.

The cup 33 is configured to receive the processing liquid scattered from the wafer W. The cup 33 has two drain openings 33a and 33b, and is configured to be movable up and down by a non-illustrated elevating mechanism. The two drain openings 33a and 33b are connected to the liquid draining mechanisms 34 and 35, respectively.

The liquid draining mechanisms 34 and 35 drains the processing liquid collected into the drain openings 33a and 33b. The liquid draining mechanism 34 is equipped with a recovery path 34b and a waste path 34c which are switched by a path switching device 34a. The recovery path 34b is, for example, a path for collecting the processing liquid to reuse it, and the waste path 34c is a path for draining out the processing liquid.

Further, a cooling buffer 34d configured to cool the electroless plating liquid, when the processing liquid is the electroless plating liquid, is provided at an outlet side of the recovery path 34b. The liquid draining mechanism 35 only has a waste path 35a.

Furthermore, though the processing liquid is supplied onto the wafer W through the nozzle 32c in the first exemplary embodiment, the device configured to supply the processing liquid onto the wafer W is not limited to the nozzle, and various other types of devices may be used.

<Outline of CMP Processing Unit>

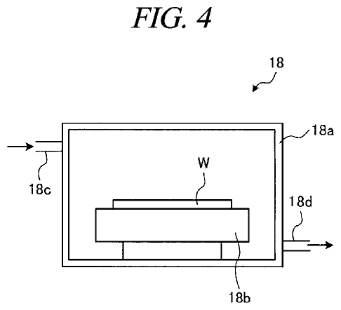

Now, referring to FIG. 3, a schematic configuration of the CMP processing unit 17 will be described. FIG. 3 is a schematic diagram illustrating the configuration of the CMP processing unit 17 according to the first exemplary embodiment. The CMP processing unit 17 is configured as, for example, a single-wafer type processing unit configured to process the wafers W one by one.

The CMP processing unit 17 is equipped with a rotary table 17a, a rotation shaft 17b, a polishing pad 17c and a nozzle 17d. The rotary table 17a is configured to hold the wafer Won a top surface thereof and is capable of spinning the wafer W held thereon.

The polishing pad 17c is provided at a lower end of the rotation shaft 17b. The rotation shaft 17b is capable of spinning the polishing pad 17c substantially in parallel with the wafer W held on the rotary table 17a, and also capable of moving the polishing pad 17c on the wafer W in a horizontal direction and a vertical direction.

The nozzle 17d is connected to a non-illustrated abrasive supply mechanism, and is configured to supply an abrasive fed from the abrasive supply mechanism onto the wafer W held by the rotary table 17a.

In the CMP processing unit 17, the preset abrasive is supplied while the rotary table 17a and the polishing pad 17c are rotated while the polishing pad 17c is being pressed onto the wafer W held on the rotary table 17a. Through this operation, the CMP processing unit 17 removes a protruding portion of a film protruded from a top surface of the wafer W by touching-up through chemical action and mechanical polishing.

As stated so far, the CMP processing unit 17 processes the wafer W with the wafer W facing upwards, and is capable of flattening the surface of the wafer W by removing only the protruding portion of the film formed on the wafer W by touching-up. Thus, since the CMP processing unit 17 according to the first exemplary embodiment can be miniaturized, it can be provided within the multilayer wiring forming system 1, so that an in-line processing is enabled.

Furthermore, though the abrasive is supplied onto the wafer W by using the nozzle 17d in the first exemplary embodiment, the device configured to supply the abrasive onto the wafer W is not limited to the nozzle, and various other types of devices can be utilized.

<Outline of Heat Treatment Unit>

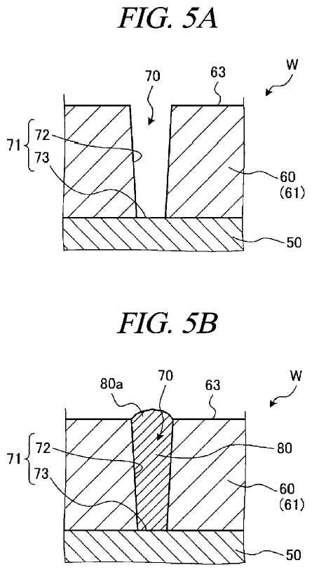

Now, referring to FIG. 4, a schematic configuration of the heat treatment unit 18 will be described. FIG. 4 is a cross sectional view illustrating the configuration of the heat treatment unit 18 according to the first exemplary embodiment. The heat treatment unit 18 is configured as, for example, a single-wafer type processing unit configured to process the wafers W one by one.

As depicted in FIG. 4, the heat treatment unit 18 includes a sealable housing 18a and a hot plate 18b disposed within the housing 18a. Further, the housing 18a is provided with a transfer port (not shown) through which the wafer W is carried in and out; a gas supply port 18c through which a preset atmosphere gas is supplied into the housing 18a; and a gas exhaust port 18d through which the atmosphere gas is exhausted from the inside of the housing 18a.

The wafer W is carried in through the transfer port to be placed on the hot plate 18b. Then, by increasing a temperature of the hot plate 18b to a predetermined value while supplying an atmosphere gas corresponding to a heat treatment, the preset heat treatment is performed on the wafer W.

<Details of Multilayer Wiring Forming Processing (First Exemplary Embodiment)>

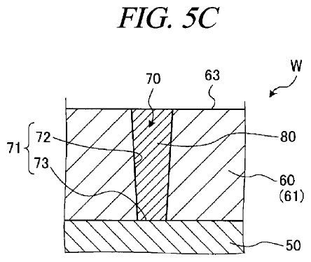

Now, referring to FIG. 5A to FIG. 5C, details of a multilayer wiring forming processing according to the first exemplary embodiment will be described. FIG. 5A to FIG. 5C are first to third schematic diagrams for describing the multilayer wiring forming processing according to the first exemplary embodiment.

Further, the wafer W shown in FIG. 5A to FIG. 5C is provided with a non-illustrated device already formed thereon. Below, various kinds of processings for filling a via 70, which is formed in an insulating film 60 on a wiring 50, with a metal wiring in a wiring forming process after the formation of the device (so-called BEOL (Back End of Line)) will be explained.

As depicted in FIG. 5A, the wiring 50 made of a metal is formed on the wafer W, and the insulating film 60 is formed on the wiring 50. This insulating film 60 includes an oxide film 61. In the first exemplary embodiment, the entire insulating film 60 is composed of the oxide film 61.

The wiring 50 according to the first exemplary embodiment is made of a component which does not diffuse into the oxide film 61. By way of non-limiting example, the wiring 50 is made of a conductive material including Co, Ni or Ru.

Further, the wafer W has the via 70 formed at a preset position in the insulating film 60. This via 70 is formed to extend from a top surface 63 of the insulating film 60 to the wiring 50. The via 70 has an inner surface 71, and the inner surface 71 includes a side surface 72 and a bottom surface 73 at which the wiring 50 is exposed.

Here, as a way to form the via 70 in the insulating film 60 of the wafer W, a commonly known method in the art may be appropriately employed. To be specific, a general-purpose technique using a fluorine-based gas, a chlorine-based gas, or the like may be utilized as a dry etching technique, for example.

Particularly, in order to form the via 70 having a high aspect ratio (a ratio of a depth to a diameter), an ICP-RIE (Inductively Coupled Plasma Reactive Ion Etching) technique capable of performing a high-speed deep etching may be adopted.

By way of example, a so-called Bosch process in which an etching process using sulfur hexafluoride (SF₆) and a protection process using a C₄F₈ gas or the like are repeatedly performed may be appropriately adopted.

As illustrated in FIG. 5A, the wafer W having the via 70 in the insulating film 60 on the wiring 50 is carried into the aforementioned electroless plating unit 16 and subjected to the preset electroless plating processing. In this electroless plating processing, the electroless plating liquid as the processing liquid is discharged onto the wafer W by using the processing liquid supply 32a of the electroless plating unit 16.

Accordingly, as shown in FIG. 5B, an electroless plating film 80 is formed from a bottom surface 73 of the via 70 in a bottom-up manner by using the wiring 50 exposed at the bottom surface 73 of the via 70 as a catalyst, and the inside of the via 70 is filled with the electroless plating film 80. Further, the electroless plating film 80 buried within the via 70 is protruded, above the via 70, from the top surface 63 of the insulating film 60. That is, a protruding portion 80a is formed at a top portion of the electroless plating film 80.

As stated above, in the first exemplary embodiment, the electroless plating film 80 is formed from the bottom surface 73 in the bottom-up manner by using the wiring 50 exposed at the bottom surface 73 as the catalyst, and the inside of the via 70 is thus filled with the electroless plating film 80. Accordingly, it is possible to form a metal wiring without having a void or a seam within the via 70 which has a high aspect ratio and in which the metal wiring is difficult to form.

Furthermore, in the first exemplary embodiment, the electroless plating film 80 needs to be formed of a material which does not diffuse in the oxide film 61 included in the insulating film 60. In such a case, since the electroless plating film 80 filling the inside of the via 70 can be suppressed from being diffused into the oxide film 61 from a side surface 72 of the via 70, reliability of the multilayer wiring can be maintained high.

By way of example, in the first exemplary embodiment, the electroless plating film 80 needs to contain Co and W or Ni. In case that the electroless plating film 80 contains Co and W, the electroless plating film 80 needs to contain 1 at % to 20 at % of tungsten (W), and the rest thereof needs to be formed of Co and an inevitable impurity. With this composition, it is possible to suppress the electroless plating film 80 filling the inside of the via 70 from being diffused into the oxide film 61.

Further, in the first exemplary embodiment, the wiring 50 needs to contain Co, Ni or Ru. With this composition, it is possible to form the electroless plating film 80 efficiently from the bottom surface 73 of the via 70 by using the wiring 50 containing Co, Ni or Ru as the catalyst.

In addition, in the first exemplary embodiment, since the electroless plating film 80 is formed by using the wiring 50 as the catalyst, the wiring 50 and the electroless plating film 80 are allowed to be in contact with each other without a barrier film, a seed film, or the like therebetween. Accordingly, the electric resistance of the metal wiring formed within the via 70 can be reduced.

Subsequently, the wafer W having the electroless plating film 80 buried in the via 70 is carried into the aforementioned CMP processing unit 17 and subjected to the preset CMP processing. By way of example, this CMP processing is performed by supplying the preset abrasive while rotating the rotary table 17a and the polishing pad 17c in the state that the polishing pad 17c is pressed onto the wafer W held on the rotary table 17a.

As a result, as depicted in FIG. 5C, the protruding portion 80a protruded from the top surface 63 of the insulating film 60 at the top portion of the electroless plating film 80 is removed by the touching-up, so that the surface of the wafer W is flattened.

As stated above, in the first exemplary embodiment, since the protruding portion 80a can be flattened by being touched up without needing to peel the entire surface of the wafer W by the CMP processing, the top surface 63 of the insulating film 60 can be suppressed from being peeled off unnecessarily.

Thereafter, the wafer W in which the protruding portion 80a of the electroless plating film 80 is removed is carried into the aforementioned heat treatment unit 18 and subjected to the preset heat treatment. In this heat treatment, by heating the hot plate 18b on which the wafer W is placed under a forming gas atmosphere in which, for example, a nitrogen gas and a hydrogen gas are mixed at a preset ratio, the temperature of the wafer W placed on the hot plate 18b is increased to the predetermined value (for example, 400° C.).

As described above, by performing the heat treatment on the electroless plating film 80, the electroless plating film 80 can be crystalized, so that the electric resistance of the metal wiring formed within the via 70 can be reduced.

Then, the wafer W having the heat-treated electroless plating film 80 is carried into the aforementioned cleaning unit 19 and subjected to the preset cleaning processing. By way of example, this cleaning processing is performed by discharging a preset cleaning liquid onto the wafer W while spinning the wafer W. Through this cleaning processing, the abrasive or the like which has adhered to the surface of the wafer Win the CMP processing is removed.

According to the first exemplary embodiment, through the various kinds of processings described so far, it is possible to fill the inside of the via 70 having the high aspect ratio with the metal wiring.

The multilayer wiring forming method according to the first exemplary embodiment includes the process of filling the via 70, which is formed in the insulating film 60 including the oxide film 61 formed on the wiring 50 of the substrate (wafer W) and is extended to the wiring 50, by forming the electroless plating film 80, which does not diffuse into the oxide film 61, from the bottom surface 73 of the via 70 while using the wiring 50, which is exposed at the bottom surface 73 of the via 70, as the catalyst. Accordingly, it is possible to efficiently form the metal wiring within the via 70 having the high aspect ratio.

Further, in the multilayer wiring forming method according to the first exemplary embodiment, the wiring 50 contains Co, Ni or Ru. Accordingly, it is possible to form the electroless plating film 80 from the bottom surface 73 of the via 70 efficiently by using the wiring 50 containing Co, Ni or Ru as the catalyst.

Furthermore, in the multilayer wiring forming method according to the first exemplary embodiment, the electroless plating film 80 contains Co and W. Accordingly, it is possible to effectively suppress the electroless plating film 80 filling the inside of the via 70 from being diffused into the oxide film 61.

In addition, in the multilayer wiring forming method according to the first exemplary embodiment, the electroless plating film 80 contains 1 at % to 20 at % of W, and the rest thereof is formed of Co and the inevitable impurity. Accordingly, it is possible to effectively suppress the electroless plating film 80 filling the inside of the via 70 from being diffused into the oxide film 61.

Moreover, in the multilayer wiring forming method according to the first exemplary embodiment, the electroless plating film 80 contains Ni. Accordingly, it is possible to effectively suppress the electroless plating film 80 filling the inside of the via 70 from being diffused into the oxide film 61.

Further, the recording medium according to the first exemplary embodiment is a computer-readable recording medium which is executed on the computer and in which the programs for controlling the multilayer wiring forming system 1 are stored. When executed, the programs allow the computer to control the multilayer wiring forming system 1 to perform the above-described multilayer wiring forming method. Accordingly, it is possible to form the metal wiring within the via 70 having the high aspect ratio.

### Second Exemplary Embodiment

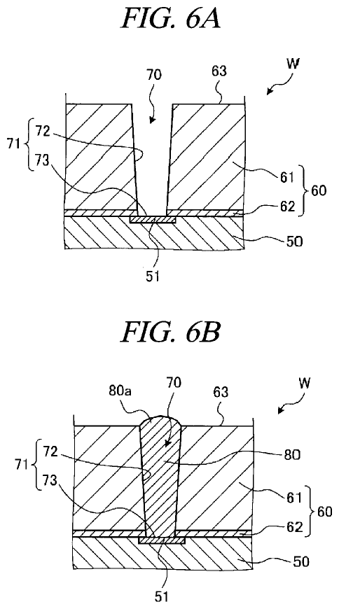

Now, referring to FIG. 6A to FIG. 6C, details of a multilayer wiring forming processing according to a second exemplary embodiment will be explained. FIG. 6A to FIG. 6C are first to third schematic diagrams for describing the multilayer wiring forming processing according to the second exemplary embodiment.

As depicted in FIG. 6A, in the second exemplary embodiment as well, a wafer W is provided with a wiring 50 made of a metal; and an insulating film 60 formed on the wiring 50. Meanwhile, in the second exemplary embodiment, the wiring 50 is formed of an element which diffuses into the oxide film 60, unlike in the first exemplary embodiment. The wiring 50 may be made of a conductive material including, by way of example, Cu.

Thus, in the second exemplary embodiment, the insulating film 60 includes an oxide film 61 and a nitride film 62. To elaborate, the nitride film 62 is formed to have a preset thickness on the wiring 50, and the oxide film 61 is formed to have a predetermined thickness on the nitride film 62. The nitride film 62 serves as a barrier film for suppressing the element of the wiring 50, which diffuses in the oxide film 61, from being diffused into the oxide film 61.

Further, in the second exemplary embodiment, to suppress the Cu or the like within the wiring 50 from being diffused into a metal wiring formed within a via 70, a barrier film 51 is previously formed at a portion of a top surface of the wiring 50 corresponding to where the via 70 is to be formed. Then, the via 70 is formed within the insulating film 60 to correspond to where the barrier film 51 is formed, as illustrated in FIG. 6A. That is, in the second exemplary embodiment, the barrier film 51 is exposed from a bottom surface 73 of the via 70.

This barrier film 51 may be made of, by way of non-limiting example, a Co—W—B alloy. As stated, since the barrier film 51 is formed of the Co—W—B alloy, the diffusion of the Cu into the metal wiring formed within the via 70 can be suppressed effectively. Further, in an electroless plating processing to be described later, it is possible to use the barrier film 51 as a catalyst for an electroless plating film 80.

Then, the wafer W having the via 70 formed in the insulating film 60 on the wiring 50 is transferred into the above-described electroless plating unit 16 and subjected to the preset electroless plating processing. In this electroless plating processing, an electroless plating liquid as a processing liquid is discharged onto the wafer W by using the processing liquid supply 32a of the electroless plating unit 16, for example.

Accordingly, as shown in FIG. 6B, the electroless plating film 80 is formed from the bottom surface 73 of the via 70 in a bottom-up manner by using the barrier film 51 exposed at the bottom surface 73 of the via 70 as the catalyst, and the inside of the via 70 is filled with the electroless plating film 80. Further, in the second exemplary embodiment as well, a protruding portion 80a is formed at a top portion of the electroless plating film 80.

As stated above, in the second exemplary embodiment, the electroless plating film 80 is formed from the bottom surface 73 in the bottom-up manner by using the barrier film 51 exposed at the bottom surface 73 as the catalyst, and the inside of the via 70 is thus filled with the electroless plating film 80. Accordingly, it is possible to form the metal wiring without having a void or a seam within the via 70 which has a high aspect ratio and in which the metal wiring is difficult to form.

In the second exemplary embodiment, the electroless plating film 80 needs to be formed of a material which does not diffuse in the oxide film 61 belonging to the insulating film 60, the same as in the first exemplary embodiment. Accordingly, since the electroless plating film 80 filling the inside of the via 70 can be suppressed from being diffused into the oxide film 61 from a side surface 72 of the via 70, reliability of the multilayer wiring can be maintained high.

In the second exemplary embodiment, the electroless plating film 80 needs to contain Co and W or Ni, the same as in the first exemplary embodiment. In case that the electroless plating film 80 contains Co and W, the electroless plating film 80 needs to contain 1 at % to 20 at % of W, and the rest thereof needs to be formed of Co and an inevitable impurity. With this composition, it is possible to effectively suppress the electroless plating film 80 filling the inside of the via 70 from being diffused into the oxide film 61.

Further, in the second exemplary embodiment, the wiring 50 needs to contain Cu. With this composition, it is possible to reduce electric resistance of the wiring 50.

Thereafter, the wafer W having the via 70 filled with the electroless plating film 80 is carried into the aforementioned CMP processing unit 17 and subjected to a preset CMP processing. The CMP processing may be performed under the same conditions as those of the above-described first exemplary embodiment. As a result of this CMP processing, as illustrated in FIG. 6C, the protruding portion 80a protruded from the top surface 63 of the insulating film 60 at the top portion of the electroless plating film 80 is removed by touching-up, so that a surface of the wafer W is flattened.

As stated above, in the second exemplary embodiment as well, since the protruding portion 80a can be flattened by being touched up without needing to peel the entire surface of the wafer W by the CMP processing, the top surface 63 of the insulating film 60 can be suppressed from being peeled off unnecessarily.

Thereafter, the wafer W in which the protruding portion 80a of the electroless plating film 80 is removed is carried into the aforementioned heat treatment unit 18 and subjected to a preset heat treatment. This heat treatment may be performed under the same conditions as those of the above-described first exemplary embodiment. As stated above, by performing the heat treatment on the electroless plating film 80, the electroless plating film 80 can be crystalized, so that the electric resistance of the metal wiring formed within the via 70 can be reduced.

Then, the wafer W having the heat-treated electroless plating film 80 is carried into the aforementioned cleaning unit 19 and subjected to a preset cleaning processing. This cleaning processing may be performed under the same conditions as those of the first exemplary embodiment. Through this cleaning processing, an abrasive or the like which has adhered to the surface of the wafer W in the CMP processing is removed.

According to the second exemplary embodiment, through the various kinds of processings described so far, it is possible to fill the inside of the via 70 having the high aspect ratio with the metal wiring even in case that the wiring 50 contains the Cu.

Further, though the above second exemplary embodiment has been described for the example where the via 70 is formed after the barrier film 51 is previously formed in the wiring 50, the barrier film 51 may be formed on the bottom surface 73 of the via 70 after the via 70 is formed.

The multilayer wiring forming method according to the second exemplary embodiment includes the process of filling the via 70, which is formed in the insulating film 60 including the oxide film 61 formed on the wiring 50 of the substrate (wafer W) and is extended to the wiring 50, by forming the electroless plating film 80, which does not diffuse into the oxide film 61, from the bottom surface 73 of the via 70 while using the barrier film 51, which is exposed at the bottom surface 73 of the via 70, as the catalyst. Accordingly, even if the wiring 50 contains the Cu, it is possible to fill the inside of the via 70 having the high aspect ratio with the metal wiring.

Furthermore, in the multilayer wiring forming method according to the second exemplary embodiment, the wiring 50 contains the Cu. Accordingly, the electric resistance of the wiring 50 can be reduced.

<Details of Multilayer Wiring Forming Processings>

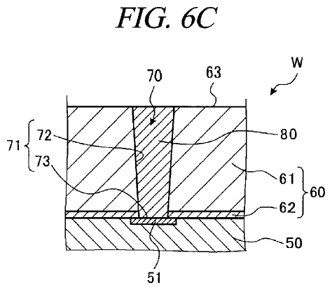

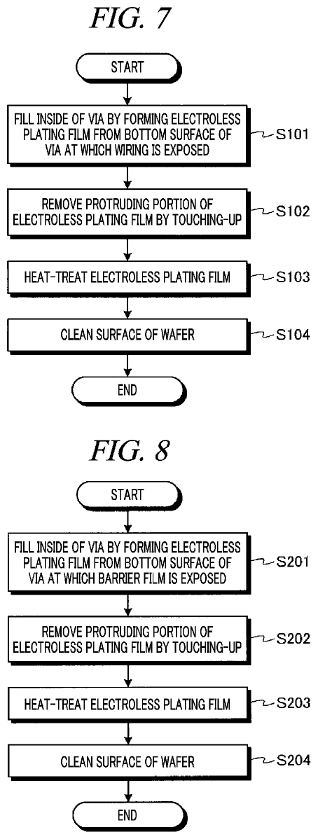

Now, refereeing to FIG. 7 and FIG. 8, details of the multilayer wiring forming processings according to the respective exemplary embodiments will be explained. FIG. 7 is a flowchart illustrating a processing sequence of the multilayer wiring forming processing according to the first exemplary embodiment.

The multilayer wiring forming processings shown in FIG. 7 and FIG. 8 are performed as the controller 21 reads out the programs installed to the storage 22 from the recording medium according to the respective exemplary embodiments and the controller 21 controls the transfer section 15, the electroless plating unit 16, the CMP processing unit 17, the heat treatment unit 18, the cleaning unit 19, and so forth based on read-out commands.

First, the wafer W having the via 70 formed in the insulating film 60 on the wiring 50 is carried from the carrier C into the electroless plating unit 16 via the substrate transfer device 13, the delivery unit 14 and the substrate transfer device 20.

Then, the controller 21 controls the electroless plating unit 16 to perform the electroless plating processing on the wafer W to thereby form the electroless plating film 80 from the bottom surface 73 of the via 70 at which the wiring 50 is exposed and fill the inside of the via 70 (process S101).

For example, this electroless plating processing is implemented by discharging the electroless plating liquid onto the wafer W and forming the electroless plating film 80 from the bottom surface 73 in the bottom-up manner with the wiring 50 exposed at the bottom surface 73 as the catalyst.

Subsequently, the controller 21 controls the substrate transfer device 20 to transfer the wafer W into the CMP processing unit 17 from the electroless plating unit 16. Then, the controller 21 controls the CMP processing unit 17 to perform the CMP processing on the wafer W to thereby remove the protruding portion 80a formed at the top portion of the electroless plating film 80 by touching-up (process S102).

For example, this CMP processing is performed by supplying the preset abrasive while rotating the rotary table 17a and the polishing pad 17c in the state that the polishing pad 17c is pressed onto the wafer W held on the rotary table 17a.

Next, the controller 21 controls the substrate transfer device 20 to transfer the wafer W into the heat treatment unit 18 from the CMP processing unit 17. Then, the controller 21 controls the heat treatment unit 18 to perform the heat treatment on the wafer W to thereby heat-treat the electroless plating film 80 (process S103).

For example, this heat treatment is implemented by raising the temperature of the wafer W to the preset value by heating, in the forming gas atmosphere, the hot plate 18b on which the wafer W is placed.

Then, the controller 21 controls the substrate transfer device 20 to transfer the wafer W into the cleaning unit 19 from the heat treatment unit 18. Then, the controller 21 controls the cleaning unit 19 to perform the cleaning processing on the wafer W to thereby clean the surface of the wafer W (process S104).

For example, this cleaning processing is implemented by discharging the preset cleaning liquid onto the wafer W to thereby remove the abrasive or the like left on the surface of the wafer W with the cleaning liquid. If this cleaning processing is completed, the multilayer wiring forming processing on the wafer W according to the first exemplary embodiment is ended.

FIG. 8 is a flowchart illustrating a processing sequence of the multilayer wiring forming processing according to the second exemplary embodiment. First, the wafer W having the via 70 formed in the insulating film 60 on the wiring 50 is carried from the carrier C into the electroless plating unit 16 via the substrate transfer device 13, the delivery unit 14 and the substrate transfer device 20.

Then, the controller 21 controls the electroless plating unit 16 to perform the electroless plating processing on the wafer W to thereby form the electroless plating film 80 from the bottom surface 73 of the via 70 at which the barrier film 51 is exposed and fill the inside of the via 70 (process S201).

For example, this electroless plating processing is implemented by discharging the electroless plating liquid onto the wafer W and forming the electroless plating film 80 from the bottom surface 73 in the bottom-up manner with the barrier film 51 exposed at the bottom surface 73 as the catalyst.

Subsequently, the controller 21 controls the substrate transfer device 20 to transfer the wafer W into the CMP processing unit 17 from the electroless plating unit 16. Then, the controller 21 controls the CMP processing unit 17 to perform the CMP processing on the wafer W to thereby remove the protruding portion 80a formed at the top portion of the electroless plating film 80 by touching-up (process S202). Since the process S202 is the same as the above-described process S102, detailed description thereof will be omitted here.

Next, the controller 21 controls the substrate transfer device 20 to transfer the wafer W into the heat treatment unit 18 from the CMP processing unit 17. Then, the controller 21 controls the heat treatment unit 18 to perform the heat treatment on the wafer W to thereby heat-treat the electroless plating film 80 (process S203). Since the process S203 is the same as the above-described process S103, detailed description thereof will be omitted here.

Then, the controller 21 controls the substrate transfer device 20 to transfer the wafer W into the cleaning unit 19 from the heat treatment unit 18. Then, the controller 21 controls the cleaning unit 19 to perform the cleaning processing on the wafer W to thereby clean the surface of the wafer W (process S204). Since the process S204 is the same as the above-described process S104, detailed description thereof will be omitted here. If this cleaning processing is completed, the multilayer wiring forming processing on the wafer W according to the second exemplary embodiment is completed.

Moreover, in the processing sequences of the exemplary embodiments described above, the electroless plating film 80 is heat-treated after the protruding portion 80a is removed by the CMP processing. However, the protruding portion 80a may be removed by the CMP processing after the electroless plating film 80 is heat-treated.

So far, the exemplary embodiments have been described. However, the present discloser is not limited to the above-described exemplary embodiments, and various changes and modifications may be made without departing from the spirit and the scope of the present disclosure. By way of example, though the entire insulating film 60 is composed of the oxide film 61 in the first exemplary embodiment, the insulating film 60 may be composed of the oxide film 61 and the nitride film 62 in the first exemplary embodiment, the same as in the second exemplary embodiment.

It should be noted that the above-described exemplary embodiments are illustrative in all aspects and are not anyway limiting. The above-described exemplary embodiments can be implemented in various ways. Further, the above-described exemplary embodiments may be omitted, replaced and modified in various ways without departing from the scope and the spirit of claims.

### EXPLANATION OF CODES

W: Wafer
1: Multilayer wiring forming system
16: Electroless plating unit
17: CMP processing unit
18: Heat treatment unit
19: Cleaning unit
21: Controller
50: Wiring
60: Insulating film
61: Oxide film
70: Via
72: Side surface
73: Bottom surface
80: Electroless plating film

1. A multilayer wiring forming method, comprising:
filling a via, which is formed in an insulating film including an oxide film formed on a wiring of a substrate and is extended to the wiring, by forming an electroless plating film, which does not diffuse into the oxide film, from a bottom surface of the via while using the wiring, which is exposed at the bottom surface of the via, as a catalyst.

2. The multilayer wiring forming method of claim 1,
wherein the wiring contains Co, Ni or Ru.

3. A multilayer wiring forming method, comprising:
filling a via, which is formed in an insulating film including an oxide film formed on a wiring of a substrate and is extended to the wiring, by forming an electroless plating film, which does not diffuse into the oxide film, from a bottom surface of the via while using a barrier film, which is exposed at the bottom surface of the via, as a catalyst.

4. The multilayer wiring forming method of claim 3,
wherein the wiring contains Cu.

5. The multilayer wiring forming method of claim 1,
wherein the electroless plating film contains Co and W.

6. The multilayer wiring forming method of claim 5,
wherein the electroless plating film contains 1 at % to 20 at % of W, and a rest of the electroless plating film is made of Co and an inevitable impurity.

7. The multilayer wiring forming method of claim 1,
wherein the electroless plating film contains Ni.

8. A computer-readable recording medium having stored thereon computer-executable instructions that, in response to execution, cause a multilayer wiring forming system to perform a multilayer wiring forming method as claimed in claim 1.
